(19) United States
(12) Patent Application Publication
(10) Pub. No.: US 2012/0051002 A1
(43) Pub. Date: Mar. 1, 2012

(54) PACKAGING STRUCTURE OF ELECTRONIC COMPONENTS AND A MANUFACTURING METHOD THEREOF

(75) Inventors: SHING-YEU JUANG, TAOYUAN COUNTY (TW); HSING-KUEI LIN, TAOYUAN COUNTY (TW)

(73) Assignee: ACSIP TECHNOLOGY INC., TAOYUAN COUNTY (TW)

(21) Appl. No.: 12/946,201

(22) Filed: Nov. 15, 2010

(30) Foreign Application Priority Data
Aug. 27, 2010 (TW) 099216580

(51) Int. Cl. H05K 9/00; H01R 43/00

(52) U.S. Cl. 361/748; 29/825

(57) ABSTRACT

A manufacturing method of a packaging structure of electronic components is provided, and includes the steps of: providing a substrate including at least an electronic component and a grounding area; covering the electronic component of the substrate with a molding unit; cutting out the molding unit to form a plurality of recessed spaces, wherein the recessed spaces are arranged around the electronic component and at least one of the recessed spaces is electrically connected to the grounding area of the substrate; and forming a plurality of columnar electromagnet barriers in the recessed spaces and an electromagnet barrier layer on an upper surface of the molding unit. A packaging structure of electronic components manufactured by the aforementioned method is also provided.

This application which claims the benefits of the Taiwan Patent Application Serial NO. 099216580 filed on Aug. 27, 2010, the subject matter of which is incorporated herein by reference.

### BACKGROUND OF THE INVENTION

1. Field of the Invention

The present invention relates to a packaging structure of electronic components and a manufacturing method thereof, and more particularly to a packaging structure of electronic components and a manufacturing method thereof which are able to block the electromagnetic interference (EMI).

2. Description of the Prior Art

In circuit design, leads, circuit boards, and/or various electronic components can generate electromagnetic waves, which may affect the overall performance of the circuit. Such a phenomenon is so-called electromagnetic interference (EMI). In practice, the EMI is unable to be completely eliminated. Actually, problems caused by the EMI can only be minimized by excellent circuit design and route design.

In related art, it is common to shield an electronic component by a metal housing, which forms a conducting barrier for blocking possible electromagnetic waves so as to reduce the effect of the EMI.

Amid the trend of miniaturization, high frequency, and higher density of distribution in electronic design, the problems of EMI can only become more troublesome and hard to be handled. Taking mobile communication products for example, it is in the trend to integrate various wireless modules such as Wi-Fi, Bluetooth, Global Positioning System (GPS), etc. into one single module. However, the application of the aforesaid three modules in a single tiny substrate or product can only make the EMI problem (mainly by interacting) more severe. It can be foreseen that, in the modern communication product, interacting EMI problem among built-in modules inside an individual system becomes a real issue.

It is easy to see that the conventional metal housing, which is applied to shield a system or equipment, is no more relevant to solve the interacting EMI problem inside a single system or module, which provides only extremely limited and irregular space for anti-EMI construction. Besides, it is also technically difficult and also expensive to manufacture tiny metal housings for individual elements in the same electronic product so as to reduce internal EMIs from those different wireless modules.

To solve various disadvantages of shielding an electronic component by a metal housing in the prior art, grooves around electronic components are cut to separate molding units of electronic components so that a grounding layer of a substrate is exposed; then the molding units are coated with a conducting coating to block the EMI. However, there are some problems in the aforementioned method of the prior art. First, since electronic components have been down-sized, for cutting the grooves on the molding units requires high accuracy and usually laser is chosen to be the cutting equipment, which increases the cost and lowers the yield rate. Moreover, the area of the conducting coating is larger, which is also a waste of recourses.

### SUMMARY OF THE INVENTION

A packaging structure of electronic components including columnar electromagnet barriers and an electromagnet barrier layer is provided according to an embodiment of the present invention, wherein the EMI is avoided without cutting out grooves on a molding unit of the packaging structure.

A manufacturing method of a packaging structure of electronic components is provided according to an embodiment of the present invention, and includes the steps of: proving a substrate including at least an electronic component and a grounding area; covering the electronic component of the substrate with a molding unit; cutting out the molding unit to form a plurality of recessed spaces, wherein the recessed spaces are arranged around the electronic component and at least one of the recessed spaces is electrically connected to the grounding area of the substrate; and forming a plurality of columnar electromagnet barriers in the recessed spaces and an electromagnet barrier layer on an upper surface of the molding unit. A packaging structure of electronic components manufactured according to the method is further provided according to an embodiment of the present invention.

According to an embodiment of the present invention, the recessed spaces are selected from the group of a via and a groove.

According to an embodiment of the present invention, the grounding area includes a ground conductor.

According to an embodiment of the present invention, the substrate includes a multi-layer board and the grounding area having a grounding layer within the multi-layer board.

A packaging structure of electronic components is provided according to an embodiment of the present invention. The packaging structure of electronic components includes a substrate, at least an electronic component, at least a molding unit, a plurality of columnar electromagnet barriers and an electromagnet barrier layer. The substrate includes at least a grounding area. The electronic component is disposed on the substrate. The molding unit covers the electronic component on the substrate and includes an upper surface. The columnar electromagnet barriers extend from the substrate to the upper surface of the molding unit. The columnar electromagnet barriers are arranged around the electronic component. At least one of the columnar electromagnet is electrically connected to the grounding area of the substrate. The electromagnet barrier layer covers the upper surface of the molding unit. The electromagnet barrier is electrically connected to the columnar electromagnet barriers.

According to an embodiment of the present invention, the substrate includes at least a via electrically connected to the grounding area.

According to an embodiment of the present invention, the electromagnet barrier layer and the columnar electromagnet barriers include a conductive coating.

According to an embodiment of the present invention, the conductive coating includes a conductive material selected from the group of a copper, a nickel, gold and aluminum.

According to an embodiment of the present invention, a material of the molding unit is selected from the group of a thermosetting resin and an epoxy resin.

Compared with a packaging structure of electronic components which blocks the EMI in the prior art, the embodiments of the present invention save the cost of coating and make manufacturing a packaging structure easier by disposing columnar electromagnet barriers around the electronic component and disposing the electromagnet barrier layer on the upper surface of the molding unit since the columnar electromagnet barriers can be made without highly accurate equipments.

### BRIEF DESCRIPTION OF THE DRAWINGS

Other features and advantages of this invention will become more apparent in the following detailed description of the preferred embodiments of this invention, with reference to the accompanying drawings, in which:

FIG. 1 is a schematic drawing of a preferred embodiment of a substrate of the present invention having at least an electronic component to be mounted thereon;

FIG. 2 is a schematic drawing of a molding unit covering the electronic components disposed on the substrate shown in FIG. 1;

FIG. 3 is a schematic drawing of a plurality of recessed spaces being cut out on the molding unit shown in FIG. 2;

FIG. 4 is a schematic drawing of an embodiment of an electromagnet barrier layer and a plurality of columnar electromagnet barriers according to the present invention;

FIG. 5 is a schematic drawing of cutting along the columnar electromagnet barriers deep down to break the substrate shown in FIG. 4;

FIG. 6 is a stereogram showing the first preferred embodiment of a packaging structure of electronic components according to the present invention;

FIG. 7 is a stereogram showing the second preferred embodiment of a packaging structure of electronic components according to the present invention; and

FIG. 8 is a cross-sectional view taken along the cutting line B-B of FIG. 7.

### DETAILED DESCRIPTION OF THE PREFERRED EMBODIMENTS

The present invention relates to a packaging structure of electronic components and a manufacturing method thereof, and more particularly to a packaging structure of electronic components and a manufacturing method thereof, which are able to block the electromagnetic interference (EMI). In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

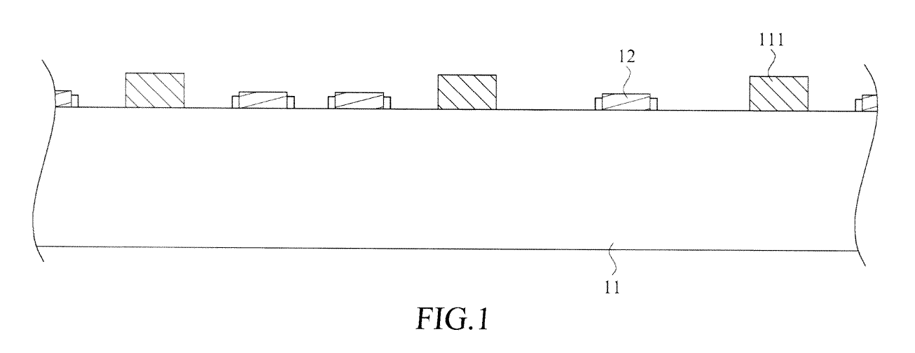

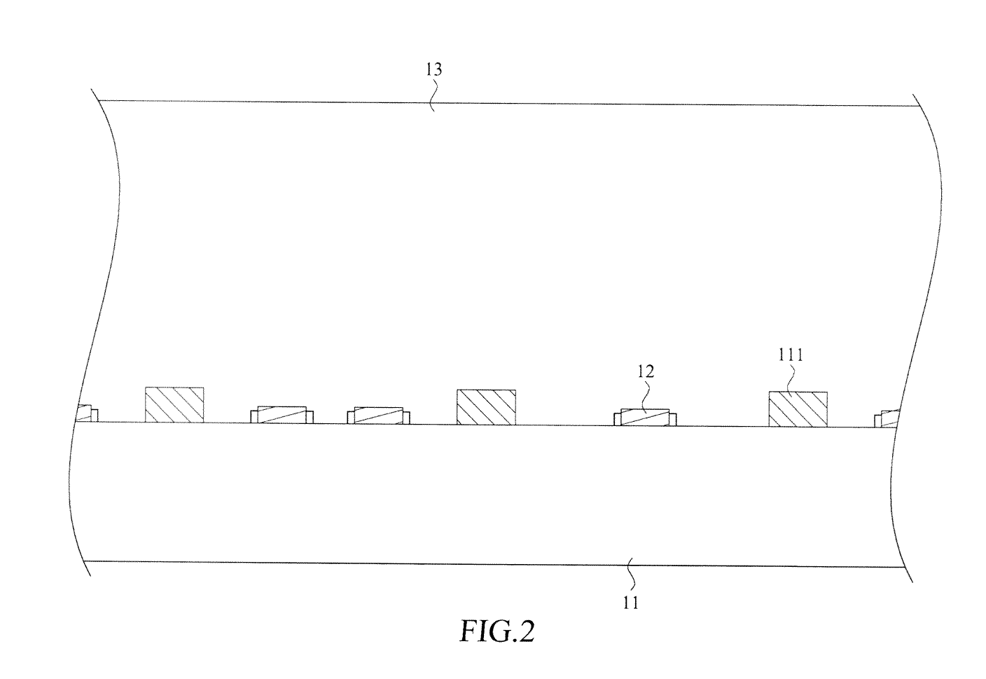

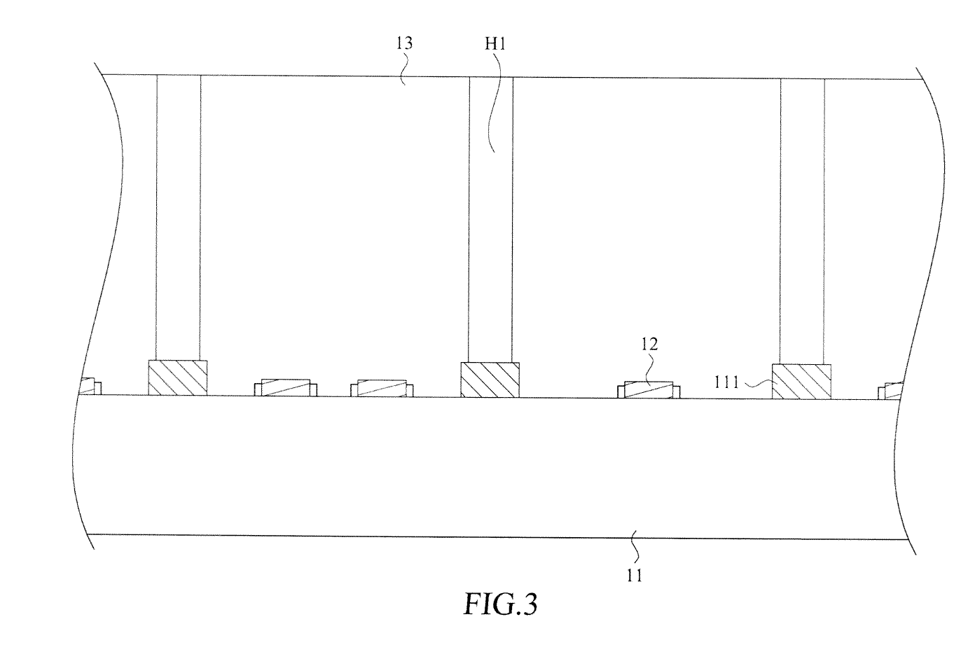

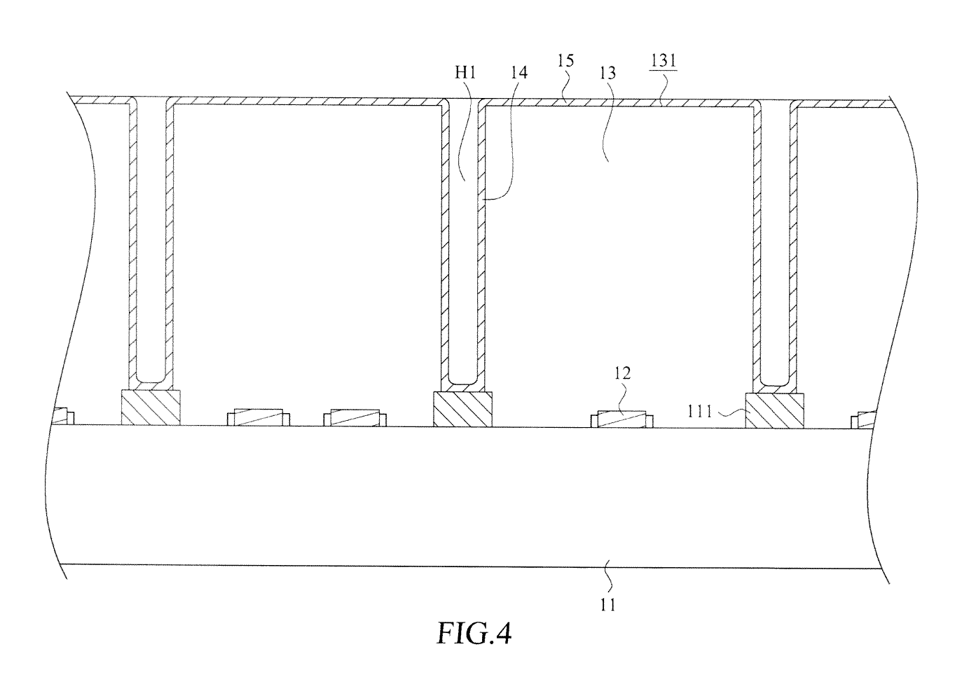

Referring to FIG. 1, FIG. 2, FIG. 3 and FIG. 4, wherein FIG. 1 is a schematic drawing of a preferred embodiment of a substrate of the present invention having at least an electronic component to be mounted thereon; FIG. 2 is a schematic drawing of a molding unit covering the electronic components disposed on the substrate shown in FIG. 1; FIG. 3 is a schematic drawing of a plurality of recessed spaces being cut out on the molding unit shown in FIG. 2; and FIG. 4 is a schematic drawing of an embodiment of an electromagnet barrier layer and a plurality of columnar electromagnet barriers according to the present invention. According to an embodiment of the present invention, a manufacturing method of a packaging structure of electronic components includes the steps of:
(a) proving a substrate 11 including at least an electronic component 12 and a grounding area 111, wherein according to an embodiment of the present invention, the grounding area has a ground conductor;
(b) covering the electronic component 12 of the substrate 11 with a molding unit 13;
(c) cutting out the molding unit 13 to form a plurality of recessed spaces H1, wherein the recessed spaces H1 are arranged around the electronic component 12 and at least one of the recessed spaces H1 is electrically connected to the grounding area 111 of the substrate 11, wherein the recessed spaces H1 are formed by an etching method or by a perforating method on the molding unit 13; and
(d) forming a plurality of columnar electromagnet barriers 14 in the recessed spaces H1 and an electromagnet barrier layer 15 on an upper surface 131 of the molding unit 13, wherein the electromagnet barrier layer 15 and the columnar electromagnet barriers 14 cooperatively form a conductive housing, which includes a conductive material selected from the group of a copper, a nickel, gold and aluminum and is fixed by a joint method selected from the group of inlaying and adhering.

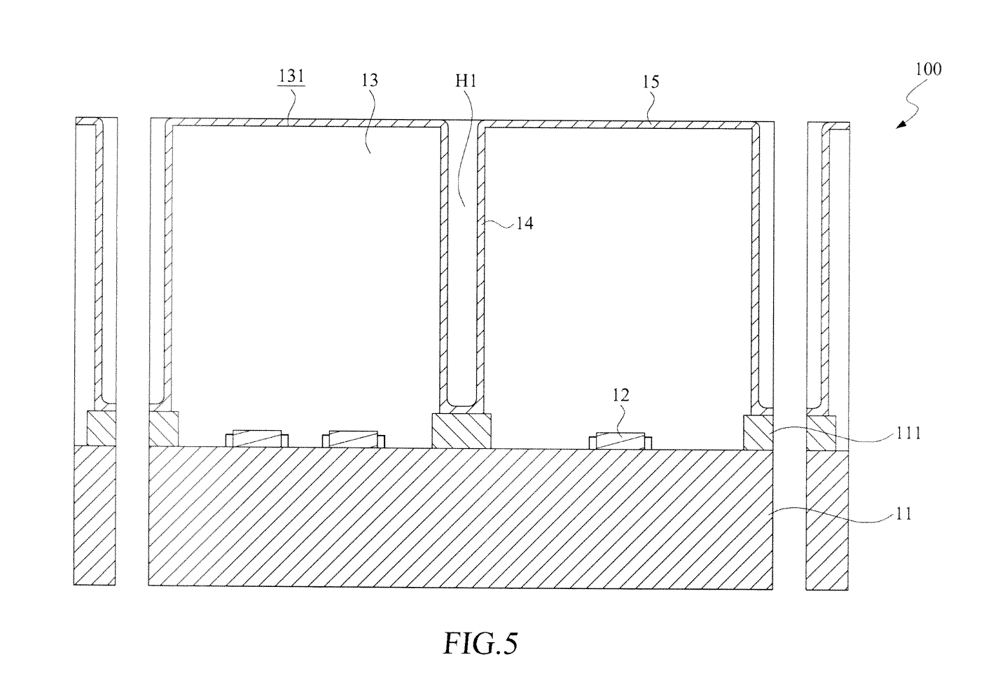

Referring to FIG. 5, FIG. 5 is a schematic drawing of cutting along the columnar electromagnet barriers deep down to break the substrate shown ion FIG. 4. After to the step (d), the manufacturing method of the packaging structure of electronic components further includes the step of:
(e) cutting along the columnar electromagnet barriers 14 deep down to break the substrate 11 so as to form the packaging structure of electronic components 100.

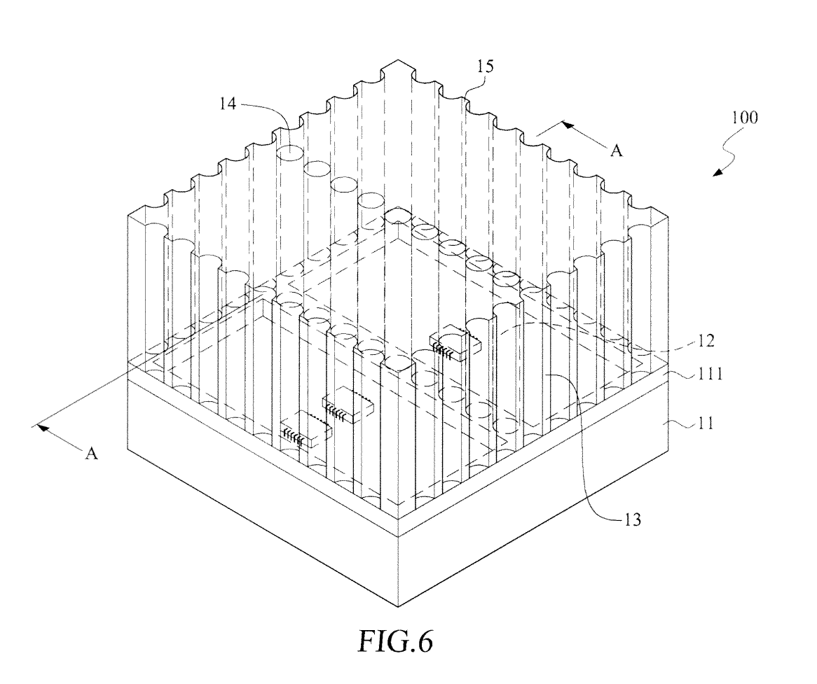

Referring to FIG. 6, FIG. 6 is a stereogram showing the first preferred embodiment of a packaging structure of electronic components according to the present invention. FIG. 5 also shows a cross-sectional view taken along the cutting line A-A of FIG. 6. It is obvious that the intervals among every columnar electromagnet barrier 14 are designed to block the EMI according to the frequency of electromagnetic wave to be blocked. Therefore, when compared to the prior art, which cuts along grooves by laser, the manufacturing method of the present invention is easier and costs less materials.

Referring to FIG. 5 and FIG. 6, which together illustrate more sufficient descriptions of an embodiment of the packaging structure of electronic components according to the present invention. An embodiment of the packaging structure of electronic components 100 is provided according to the present invention. The packaging structure of electronic components 100 includes a substrate 11, at least an electronic component 12, at least a molding unit 13, a plurality of columnar electromagnet barriers 14 and an electromagnet barrier layer 15.

According to an embodiment of the present invention, the substrate 11 includes at least a grounding area 111. The grounding area 111 has a ground conductor. The electronic component 12 is disposed on the substrate 11.

According to an embodiment of the present invention, the molding unit 13 covers the electronic component 12 on the substrate 11 and includes an upper surface 131. The material of the molding unit 13 is selected from the group of a thermosetting resin and an epoxy resin. The columnar electromagnet barriers 14 extend from the substrate 11 to the upper surface 131 of the molding unit 13 and are arranged around the electronic component 12, and at least one of the columnar electromagnet barriers 14 is electrically connected to the grounding area 111 of the substrate 11. The electromagnet barrier layer 15 covers the upper surface 131 of the molding unit 13 and is electrically connected to the columnar electromagnet barriers 14.

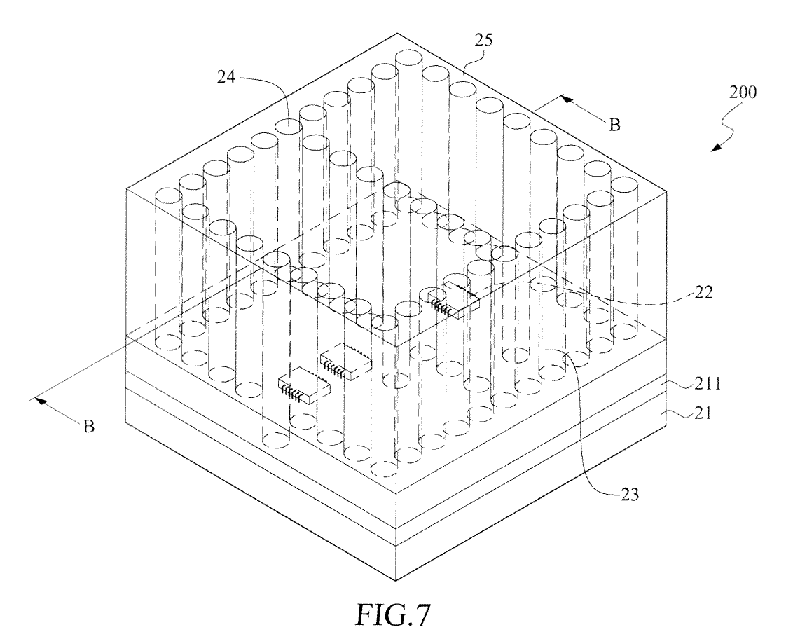

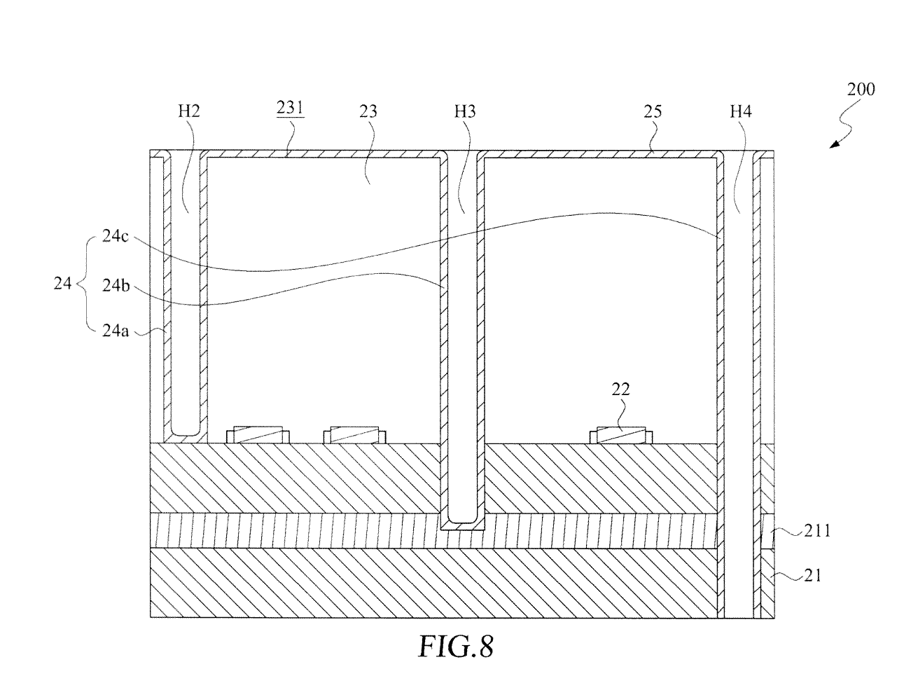

Referring to FIG. 7 and FIG. 8, wherein FIG. 7 is a stereogram showing the second preferred embodiment of the packaging structure of electronic components according to the present invention while FIG. 8 is a cross-sectional view taken along the cutting line B-B of FIG. 7. What is different from the first preferred embodiment of the present invention is that: in the first preferred embodiment of the present invention, the substrate 11 is provided with a ground conductor. According to the second preferred embodiment of the present invention, the substrate 21 is provided with a multi-layer board. In a packaging structure of electronic components 200, a grounding area 211 of a substrate 21 is disposed in a grounding layer inside the substrate 21 while at least an electronic component 22 is disposed on the substrate 21. The molding unit 23 covers around the electronic component 22 and the molding unit 23 includes an upper surface 231.

The way of arranging columnar electromagnet barriers 24 is selected from the group of a columnar electromagnet barrier 24a, extending from the grounding area 211 to the upper surface 231, a columnar electromagnet barrier 24b, extending from below the grounding area 211 to the upper surface 231, and a columnar electromagnet barrier 24c extending directly from below the substrate 21 to the upper surface 231, i.e., and going through the substrate 21. The EMI is blocked when any of the columnar electromagnet barriers 24 is electrically connected to the grounding area 211 along with an electromagnet barrier layer 25 covering the upper surface 231. Moreover, when cutting alone the columnar electromagnet barriers 24, apart from the way of cutting the columnar electromagnet barriers 14 mentioned in the first preferred embodiment of the present invention, cutting along the surroundings of the columnar electromagnet barriers 24 according to the second preferred embodiment of the present invention provides a better outlook without showing the columnar electromagnet barriers 24 in the sides of the packaging structure of electronic components 200.

In conclusion, since the columnar electromagnet barriers 14 and 24 can be made without highly accurate equipments, the cost of coating is saved and manufacturing the packaging structure also becomes easier.

While the present invention has been particularly shown and described with reference to a preferred embodiment, it will be understood by those skilled in the art that various changes in form and detail may be without departing from the spirit and scope of the present invention.

What is claimed is:

1. A manufacturing method of a packaging structure of electronic components, comprising the steps of:
(a) providing a substrate comprising at least an electronic component and a grounding area;
(b) covering the electronic component of the substrate with a molding unit;
(c) cutting out the molding unit to form a plurality of recessed spaces, wherein the recessed spaces are arranged around the electronic component and at least one of the recessed spaces is electrically connected to the grounding area of the substrate; and
(d) forming a plurality of columnar electromagnet barriers in the recessed spaces and an electromagnet barrier layer on an upper surface of the molding unit.

2. The manufacturing method according to claim 1, wherein the grounding area has a ground conductor.

3. The manufacturing method according to claim 1, wherein the substrate includes a multi-layer board and the grounding area includes a grounding layer within the multi-layer board.

4. The manufacturing method according to claim 1, wherein the recessed spaces are selected from the group of a via and a groove.

5. The manufacturing method according to claim 1, further comprising a step (e) after said step (d) cutting along the columnar electromagnet barriers deep down to break the substrate so as to form a packaging structure of electronic components.

6. A packaging structure of electronic components comprising:
a substrate including at least a grounding area;
at least an electronic component disposed on the substrate;
at least a molding unit covering said electronic component on the substrate, the molding unit having an upper surface;
a plurality of columnar electromagnet barriers extending from the substrate to the upper surface of the molding unit, the columnar electromagnet barriers being arranged around the electronic component, at least one of the columnar electromagnet barriers electrically connected to the grounding area of the substrate; and
an electromagnet barrier layer covering the upper surface of the molding unit, the electromagnet barrier being electrically connected to the columnar electromagnet barriers.

7. The packaging structure of electronic components according to claim 6, wherein the grounding area has a ground conductor.

8. The packaging structure of electronic components according to claim 6, wherein the substrate includes a multi-layer board and the grounding area includes a grounding layer within the multi-layer board.

9. The packaging structure of electronic components according to claim 6, wherein the substrate has at least a via electrically connected to the grounding area.

10. The packaging structure of electronic components according to claim 6, wherein the electromagnet barrier layer and the columnar electromagnet barriers cooperatively have a conductive coating.

11. The packaging structure of electronic components according to claim 10, wherein the conductive coating consists of a conductive material selected from the group of a copper, a nickel, gold and aluminum.

12. The packaging structure of electronic components according to claim 6, wherein a material of the molding unit is selected from the group of a thermosetting resin and an epoxy resin.
